(19) United States
(12) Patent Application Publication
(10) Pub. No.: US 2020/0251340 A1
(43) Pub. Date: Aug. 6, 2020

(54) METHODS AND APPARATUS FOR FILLING A FEATURE DISPOSED IN A SUBSTRATE

(71) Applicant: APPLIED MATERIALS, INC., Santa Clara, CA (US)

(72) Inventors: ROEY SHAVIV, Palo Alto, CA (US); AVGERINOS V. GELATOS, SCOTTS VALLEY, CA (US); ISMAIL EMESH, Sunnyvale, CA (US); XIKUN WANG, Sunnyvale, CA (US); YU LEI, Belmont, CA (US)

(21) Appl. No.: 16/775,752

(22) Filed: Jan. 29, 2020

Related U.S. Application Data
(60) Provisional application No. 62/801,075, filed on Feb. 4, 2019.

(51) Int. Cl. H01L 21/285; H01L 21/768; H01L 21/3213; H01L 21/02

(52) U.S. Cl. CPC H01L 21/28562; H01L 21/76879; H01L 21/0228; H01L 21/32136; H01L 21/76841

(57) ABSTRACT

Methods and apparatus for filling a feature disposed in a substrate, including: depositing a first metal within the feature to a first predetermined thickness in a first process chamber; etching the first metal to remove a first portion of the metal at a top of the feature in a second process chamber different than the first process chamber to form an exposed surface of the first metal, and selectively depositing a second metal atop the exposed surface of the first metal within the feature to a second predetermined thickness in a third process chamber; wherein etching the first metal and selectively depositing a second metal are performed without oxygen contacting the top surface.

### CROSS-REFERENCE TO RELATED APPLICATIONS

This application claims benefit of U.S. provisional patent application Ser. No. 62/801,075, filed Feb. 4, 2019 which is herein incorporated by reference in its entirety.

### FIELD

Embodiments of the present disclosure generally relate to methods of filling a feature disposed in a substrate and integrating at least one layer of tungsten metallization.

### BACKGROUND

Fabrication of integrated circuits and other microelectronic devices include processes to fill features formed in or on a substrate. Dimensions of the contacts to the source and drain regions, as well as the contact to the metal gate, have drastically decreased to less than 20 nm. The inventors have observed that conventional methods of filling contact plugs produce unacceptably high resistance, and the small features of the metal interconnects problematically increase a conductor's resistivity. Further, the inventors have observed that at small dimensions metals like cobalt, ruthenium, iridium, molybdenum, and tungsten exhibit lower resistivity than that of copper. While cobalt metallization is promising in narrow features, the inventors have observed that fabricating one or more, or multiple layers of metallization remains a challenge due to the difficulty in feature or via integration. Moreover, the presence of barriers or liners in features such as vias problematically cause significant increase in via resistance.

Accordingly, the inventors have developed improved techniques to fill features with a conductive material and integrate one or more layers of metallization.

### SUMMARY

Methods and apparatus for filling a feature disposed in a substrate are provided herein. In some embodiments, a method of filling a feature disposed in a substrate, includes: (a) etching a first metal within the feature to remove a first portion of the first metal at a top of the feature in a first process chamber to form an exposed surface of the first metal; and (b) selectively depositing a second metal atop the exposed surface of the first metal within the feature to a second predetermined thickness in a second process chamber; wherein etching the first metal and selectively depositing a second metal are performed without oxygen contacting the exposed surface. In embodiments, the first metal is cobalt and the second metal is tungsten.

In some embodiments, a method of filling a feature disposed in a substrate, includes: (a) depositing a first metal within the feature to a first predetermined thickness in a first process chamber; (b) etching the first metal to remove a first portion of the first metal at a top of the feature in a second process chamber different than the first process chamber to form an exposed surface of the first metal; and (c) selectively depositing a second metal atop the exposed surface of the first metal within the feature to a second predetermined thickness in a third process chamber; wherein etching the first metal and selectively depositing a second metal are performed without oxygen contacting the exposed surface. In embodiments, the first metal is cobalt and the second metal is tungsten. In embodiments, leveling the first metal by chemical mechanical planarization may occur after depositing a first metal and prior to etching the first metal.

In some embodiments, an apparatus includes a cluster tool, including: a first transfer chamber; an atomic layer etching (ALE) chamber configured to etch a first metal coupled to the first transfer chamber; and a chemical vapor deposition (CVD) chamber configured to deposit a second metal coupled to the first transfer chamber; wherein the cluster tool is configured to transfer from the atomic layer etching (ALE) chamber to the chemical vapor deposition (CVD) chamber under continuous vacuum. In embodiments, the continuous vacuum is provided in an amount sufficient to remove oxygen and/or prevent oxygen from contacting the first metal and/or second metal as desired during process sequences. In embodiments, the first metal is cobalt and the second metal is tungsten.

In some embodiments, the present disclosure relates to a computer readable medium, having instructions stored thereon which, when executed, cause at least two process chambers to perform a method of filling a feature disposed in a substrate, including: (a) etching a first metal within the feature to remove a first portion of the first metal at a top of the feature in a first process chamber to form an exposed surface of the first metal; and (b) selectively depositing a second metal atop the exposed surface of the first metal within the feature to a second predetermined thickness in a second process chamber; wherein etching the first metal and selectively depositing a second metal are performed without oxygen contacting the exposed surface. In embodiments, the first metal is cobalt and the second metal is tungsten.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart of a method of filling a feature of a substrate in accordance with some embodiments of the present disclosure.

FIGS. 2A-F depict the stages of filling and integrating a feature in a substrate in accordance with some embodiments of the present disclosure.

FIG. 3 depicts a flow chart of a method filling a feature of a substrate in accordance with some embodiments of the present disclosure.

FIG. 4 depicts an etch chamber suitable for performing a method of filling a feature in a substrate in accordance with some embodiments of the present disclosure.

FIG. 5 depicts a deposition chamber suitable for performing a method of filling a feature in a substrate in accordance with some embodiments of the present disclosure.

FIG. 6 depicts a cluster tool suitable for performing a method of filling a feature in a substrate in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods and apparatus for filling a feature in a substrate are provided herein. For example, in embodiments, a method of filling a feature disposed in a substrate, includes: (a) etching a first metal within the feature to remove a first portion of the first metal at a top of the feature in a first process chamber to form an exposed surface of the first metal; and (b) selectively depositing a second metal atop the exposed surface of the first metal within the feature to a second predetermined thickness in a second process chamber; wherein etching the first metal and selectively depositing a second metal are performed without oxygen contacting the exposed surface. The methods advantageously facilitate low via contact resistance (between one or more substrates) by using a recess of a first metal such as a cobalt inside a feature followed by selective deposition of a second metal such as tungsten. The methods may be utilized in the formation of metal interconnects in an integrated circuit, in the formation of a metal gate, or a metal-contact gap fill process, as well as other suitable applications where filling a feature may be performed such as where a barrier free via with reduced cladding and improving performance is desired. The inventors have observed other advantages such as the methods of the present disclosure can be used to fabricate low resistance stacked vias by reducing the contact resistance of vias by eliminating a liner between a lower and an upper via. In embodiments, methods of the present disclosure may advantageously be performed in the same cluster tool with no vacuum break between etching the first metal and depositing the second metal to ensure a first metal to second metal interface between the first metal and second metal has enhanced ohmic contact. Methods of the present disclosure advantageously avoid cobalt oxidation after etching, eliminating the need for a clean before the deposition of a second metal thereon such as tungsten.

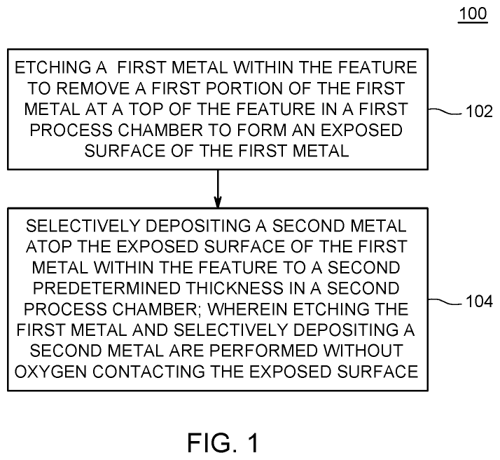

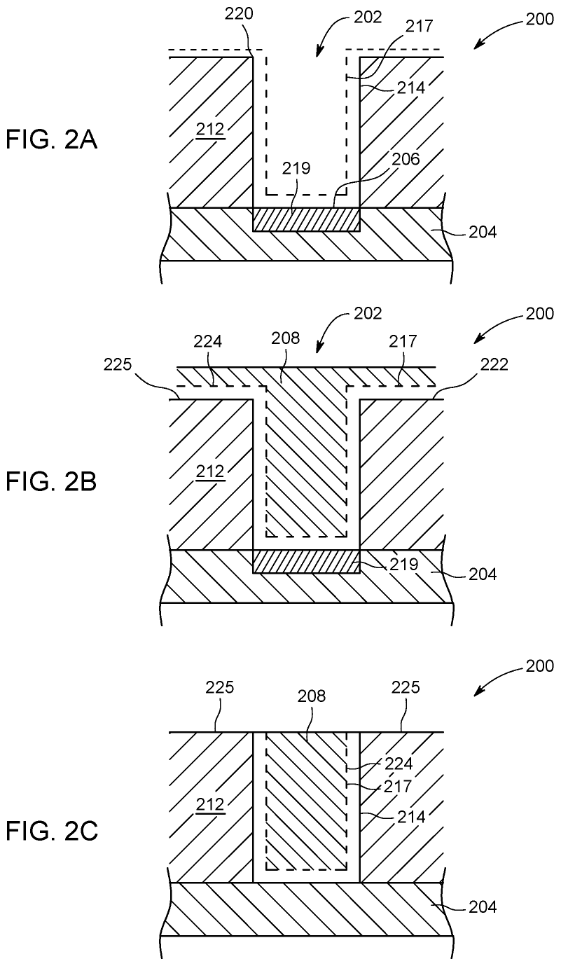

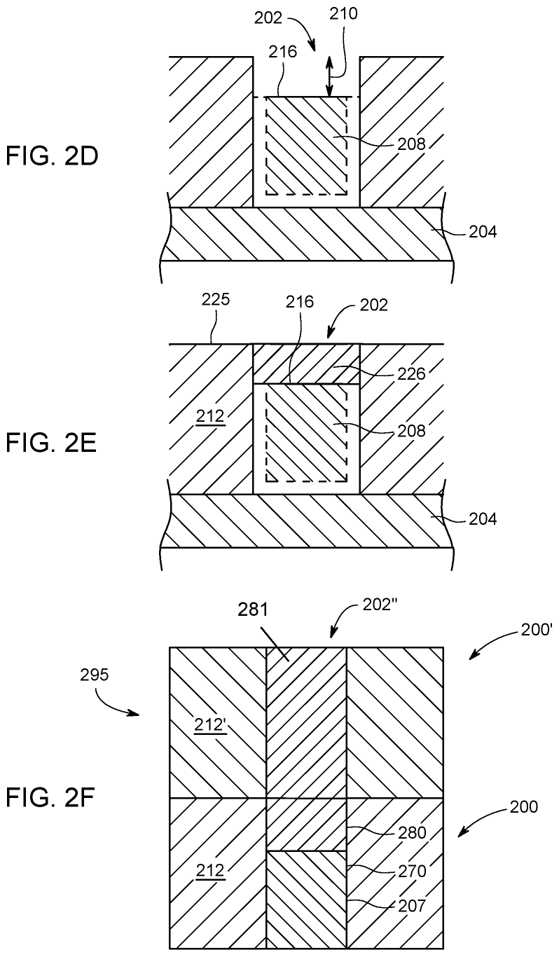

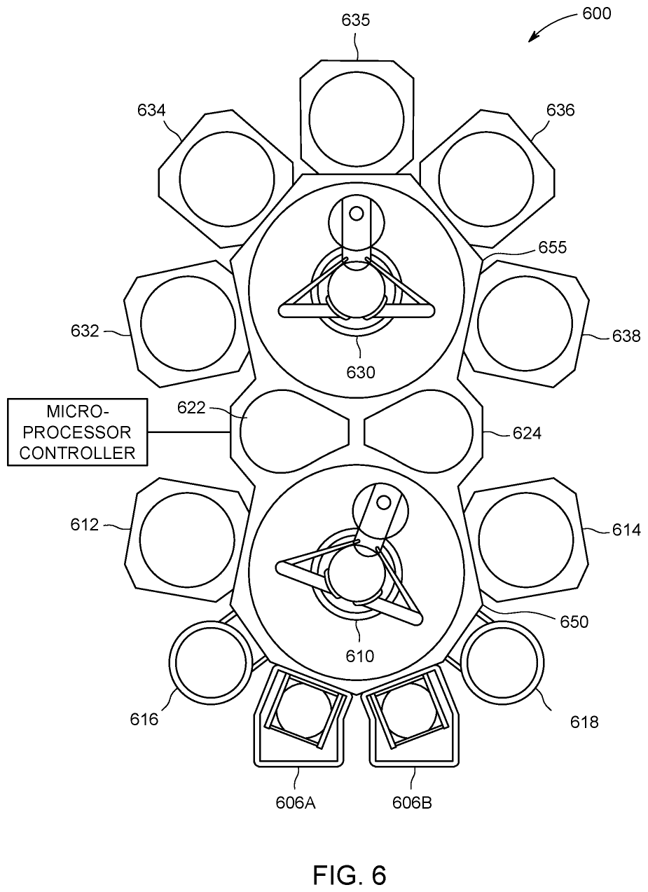

FIG. 1 depicts a flow chart of a method 100 for processing a substrate in accordance with some embodiments of the present disclosure. The method 100 is described below with respect to the stages of processing a substrate as depicted in FIGS. 2A-2F and may be performed, for example, in a suitable reactor, such as a cluster tool 600 described below in FIG. 6. Exemplary processing systems that may be used to perform the inventive methods disclosed herein may include, but are not limited to, any of the ENDURA®, CENTURA®, or PRODUCER® line of processing systems, commercially available from Applied Materials, Inc., of Santa Clara, Calif. Other process chambers, including ones available from other manufacturers, may also be suitably used in connection with the teachings provided herein.

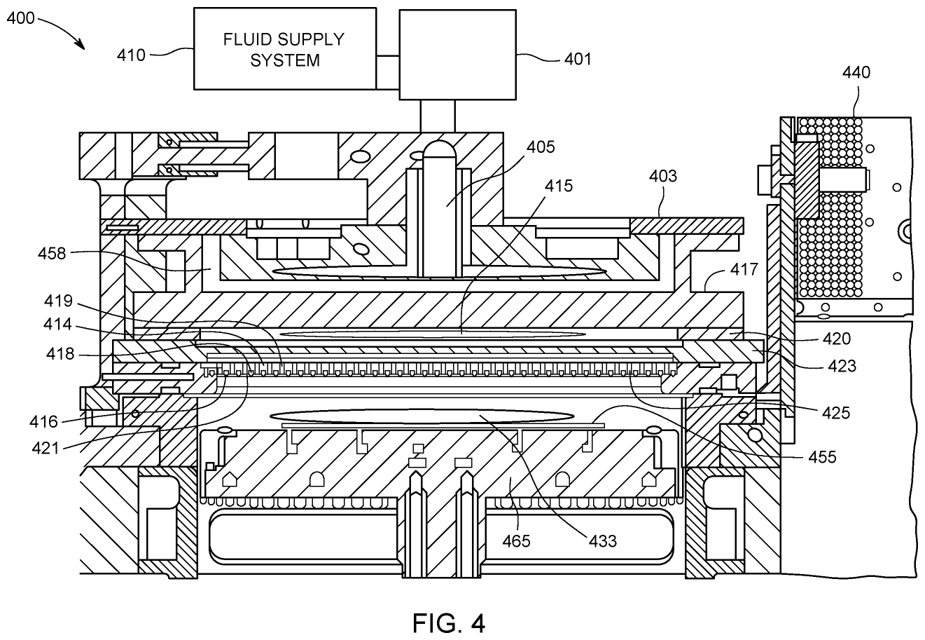

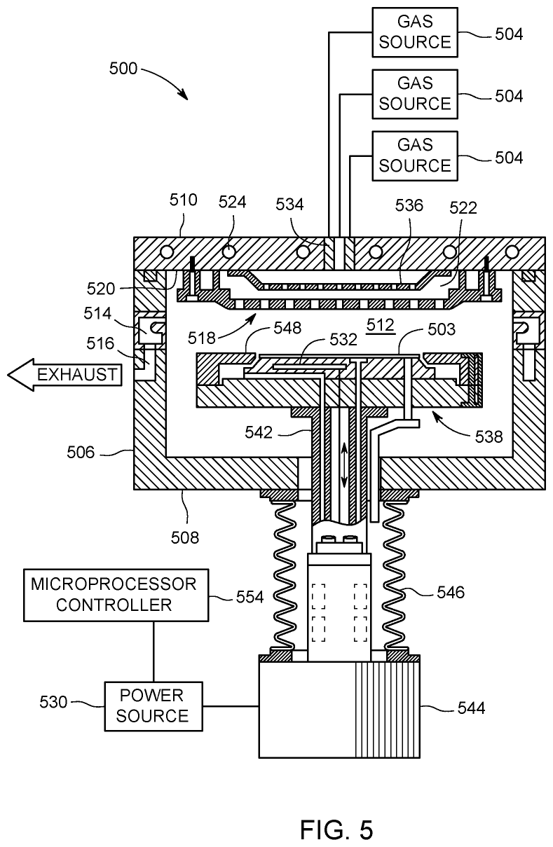

The method 100 is typically performed on a substrate 200 provided to a processing volume of a process chamber, for example substrate processing etch chamber such as process chamber 400 described below in FIG. 4, substrate processing deposition chamber such as process chamber 500 described below in FIG. 5, each chamber disposed within a cluster tool shown in FIG. 6. In some embodiments, as shown in FIG. 2A, the substrate 200 includes one or more features 202 (one shown in FIGS. 2A-2F) to be filled, formed in a layer 212 of the substrate 200, and extending towards a base 204 of the substrate 200. Although the following description is made with respect to one feature 202, the substrate 200 may include any number of features 202. In some embodiments, a device 219, such as a logic device or the like, or a portion of a device requiring electrical connectivity, such as a gate, a contact pad, a conductive via, or the like, may be disposed in the base 204 of the substrate 200 and aligned with the feature 202. Although not shown in FIG. 2A, the feature 202 may be filled with one or more conductive materials such as a first metal and a second metal to form a conductive pathway to the device 219.

The substrate 200 may be any suitable substrate having the feature 202 formed in the substrate 200. For example, the substrate 200 may comprise one or more of silicon (Si), silicon oxide (SiO₂), or the like. In some embodiments, the layer 212 may be a dielectric layer. In addition, the substrate 200 may include additional layers of materials or may have one or more completed or partially completed structures or devices formed in or on the substrate 200.

The feature 202 may be formed by etching the substrate 200 using any suitable etch process. In some embodiments, the feature 202 is defined by one or more sidewalls 214, a bottom surface 206 and upper corners 220. In some embodiments, the feature 202 may be a via, contact, trench, dual damascene, or the like. In some embodiments, the feature 202 may have a high aspect ratio, e.g., an aspect ratio between about of about 5:1 and about 15:1. As used herein, the aspect ratio is the ratio of a depth of the feature to a width of the feature.

In some embodiments, a barrier layer 217 (shown in phantom), is optionally deposited on the substrate 200 in process chamber configured to deposit the barrier layer (e.g., process chamber 500 discussed below). In embodiments, a barrier layer such as barrier layer 217 includes a layer conformably formed along at least a portion of the sidewalls and/or lower surface of a feature such that a substantial portion of the feature prior to the deposition of the layer remains unfilled after deposition of the barrier layer 217. In some embodiments, the barrier layer 217 may be formed along the entirety of the sidewalls and lower surface of the feature. In some embodiments, the barrier layer 217 is a metal containing layer. In some embodiments, the barrier layer 217 is deposited only within the feature and in some embodiments, the barrier layer 217 is disposed upon the sidewalls of the feature and atop the field of the layer 212. In some embodiments, the barrier layer 217 may contain tungsten (W), aluminum (Al), titanium (Ti), tantalum (Ta), oxides or nitrides thereof, silicides thereof, derivatives thereof, or combinations thereof. In some embodiments, the barrier layer 217 may be titanium nitride (TiN), which is deposited in a chemical vapor deposition (CVD) chamber, such as any of substrate processing chambers such as deposition chamber such as process chamber 500 discussed below.

Referring now to FIG. 2B, the feature 202 may be filled with one or more conductive materials such as a first metal 208 within the feature 202 to form a conductive pathway to the device 219. In embodiments, the first metal 208 is deposited atop a first surface 222 of the substrate 200 and within the feature 202 formed in the first surface 222. Optionally, the first metal 208 may be deposited atop a first surface 224 of the barrier layer 217 and within the feature 202 formed in the substrate 200. In embodiments, the first metal 208 may be deposited atop the field 225 of layer 212 such that feature 202 is overfilled by first metal 208. The first metal 208 may be deposited using any suitable deposition process(es), for example a PVD process, an atomic layer deposition (ALD) process, a CVD process, or electrochemical deposition (ECD) process. In some embodiments, the first metal 208 is a conductive material used to fill the feature 202, for example, to form a conductive pathway.

In some embodiments, the first metal 208 is cobalt, used to fill or overfill the feature 202, for example, to form a conductive pathway. In some embodiments, the thickness of the first metal 208 extends above the upper corners 220 of the opening of feature 202. As a result, field 225 may be covered with the first metal 208 surrounding the feature 202.

Referring to FIG. 2C, in embodiments, first metal 208 above the feature 202 and/or on field 225 is removed using chemical-mechanical planarization to form an exposed field 225 of layer 212. Further, barrier layer 217, if any, above the feature 202 is removed using chemical-mechanical planarization. In embodiments, first metal 208 completely fills feature 202 without any first metal 208 disposed upon field 225 to form a conductive pathway. In embodiments, the first metal 208 is deposited within the feature 202 formed in the first surface 222. Optionally, the first metal 208 may be deposited atop a first surface 224 of the barrier layer 217 and within the feature 202 formed in the substrate 200.

Referring to FIG. 1, and FIG. 2D, the method may begin at 102 by etching a first metal 208 within the feature 202 to remove a first portion (shown as arrow 210) of the first metal 208 at a top of the feature 202 in a first process chamber (such as process chamber 400) to form an exposed surface 216 of the first metal 208. In embodiments, first metal 208 is etched to remove a first portion (shown as arrow 210) of material created by a deposition processes as described above. During etching, the first metal 208 is oxidized using an oxidizing precursor. In some embodiments, the first metal 208 is oxidized using a plasma formed with the oxidizing precursor. In some embodiments, the first metal 208 is oxidized using the oxidizing precursor in a thermal process without the use of a plasma. In some embodiments, the oxidizing precursor includes a chlorine-containing agent. In embodiments, a purge gas is then flowed through the process chamber to purge the oxidizing precursor from the process chamber. Subsequently, the oxidized layer is then exposed to a reducing agent which etches away the oxidized layer by reacting with the oxidized layer to form a volatile organometallic. In some embodiments, the substrate is heated to a temperature between about 100° C. and about 250° C. during etching to accelerate the etch rate. Finally, a purge gas is again flowed through chamber to purge the organometallic product from the chamber. Examples of etching processes suitable for the etch process at 102 are described in commonly owned U.S. Pat. No. 10,163,696, entitled Selective Cobalt Removal For Bottom Up Gapfill, filed on Nov. 11, 2016 to inventors Xikun Wang et al. The etching process may be repeated to remove a predetermined amount of first portion (shown as arrow 210) material. In embodiments, the etching is performed to remove a first portion (shown as arrow 210) of material characterized as 1 to 30 percent, 3 to 20 percent, or 5 to 15 percent of the amount of first metal 208 in feature 202. In embodiments, the etching is performed to remove a first portion (shown as arrow 210) in the amount of 5 to 10 nanometers of material from the feature 202. In embodiments, first portion (shown as arrow 210) is removed from top down, or from the opening of the feature 202 to further within feature 202. In embodiments, the etching process may be performed between 1 and 10 times. In some embodiments, as the number of etch cycles increases, the lateral etch rate exceeds the vertical etch rate. For example, in some embodiments the lateral etch rate exceeds the vertical etch rate by about 1.6 times. In some embodiments, the first process chamber is an etch chamber and the etching is performed using atomic layer etch (ALE). In some embodiments, the first process chamber is an etch chamber configured to etch cobalt. In some embodiments, the first process chamber is an atomic layer etch chamber.

In some embodiments, the first process chamber is an etch chamber such as the etch chamber of FIG. 4, and etching the first metal includes: (1) oxidizing a top surface of the first metal within a feature using an oxidizing precursor to form an oxidized layer; (2) purging the oxidizer precursor from the etch chamber; (3) flowing a reducing agent into the etch chamber to react with the oxidized layer and form an organometallic product and etch away the oxidized layer; and (4) purging the organometallic product from the etch chamber. In some embodiments, the first process chamber is positioned within a cluster tool (such as the tool shown in FIG. 6) configured to operate without oxygen or under continuous vacuum.

A non-limiting example an exemplary etching chamber system such as process chamber 400 is shown in FIG. 4. During cobalt etching, a process gas may be flowed into the first plasma region 415 through a gas inlet assembly 405. A remote plasma system (RPS) 401 may optionally be included in the system and may process a first gas which then travels through gas inlet assembly 405. The gas inlet assembly 405 may include two or more distinct gas supply channels where the second channel (not shown) may bypass the RPS 401, if included.

A cooling plate 403, faceplate 417, ion suppressor 423, showerhead 425, and a pedestal 465, having a substrate 455 disposed thereon, are shown in FIG. 4 and may each be included according to embodiments. The pedestal 465 may have a heat exchange channel through which a heat exchange fluid flows to control the temperature of the substrate, which may be operated to heat and/or cool the substrate or wafer during processing operations. The wafer support platter of the pedestal 465, which may comprise aluminum, ceramic, or a combination thereof, may also be resistively heated in order to achieve relatively high temperatures, such as from up to or about 100 degrees Celsius to above or about 600 degrees Celsius, using an embedded resistive heater element.

The faceplate 417 may be pyramidal, conical, or of another similar structure with a narrow top portion expanding to a wide bottom portion. The faceplate 417 may additionally be flat as shown and include a plurality of through-channels used to distribute process gases. Plasma generating gases and/or plasma excited species, depending on use of the RPS 401, may pass through a plurality of holes (not shown).

Non-limiting exemplary configurations may include having the gas inlet assembly 405 open into a gas supply region 458 partitioned from the first plasma region 415 by faceplate 417 so that the gases/species flow through the holes in the faceplate 417 into the first plasma region 415. Structural and operational features may be selected to prevent significant backflow of plasma from the first plasma region 415 back into the gas supply region 458, gas inlet assembly 405, and fluid supply system 410. The faceplate 417, or a conductive top portion of the chamber, and showerhead 425 are shown with an insulating ring 420 located between the features, which allows an AC potential to be applied to the faceplate 417 relative to showerhead 425 and/or ion suppressor 423. The insulating ring 420 may be positioned between the faceplate 417 and the showerhead 425 and/or ion suppressor 423 enabling a capacitively coupled plasma (CCP) to be formed in the first plasma region. A baffle (not shown) may additionally be located in the first plasma region 415, or otherwise coupled with gas inlet assembly 405, to affect the flow of fluid into the region through gas inlet assembly 405.

In some embodiments, the showerhead 425 may comprise an upper plate 414 and a lower plate 416. The plates may be coupled with one another to define a volume 418 between the plates. The coupling of the plates may be so as to provide first fluid channels 419 through the upper and lower plates, and second fluid channels 421 through the lower plate 416. The formed channels may be configured to provide fluid access from the volume 418 through the lower plate 416 via second fluid channels 421 alone, and the first fluid channels 419 may be fluidly isolated from the volume 418 between the plates and the second fluid channels 421.

In some embodiments, the ion suppressor 423 may comprise a plate or other geometry that defines a plurality of apertures throughout the structure that are configured to suppress the migration of ionically-charged species out of the first plasma region 415 while allowing uncharged neutral or radical species to pass through the ion suppressor 423 into an activated gas delivery region between the suppressor and the showerhead. In embodiments, the ion suppressor 423 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 423 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter the etch selectivity of the gas mixture.

The plurality of apertures in the ion suppressor 423 may be configured to control the passage of the activated gas, i.e., the ionic, radical, and/or neutral species, through the ion suppressor 423. For example, the aspect ratio of the holes, or the hole diameter to length, and/or the geometry of the holes may be controlled so that the flow of ionically-charged species in the activated gas passing through the ion suppressor 423 is reduced. The holes in the ion suppressor 423 may include a tapered portion that faces the plasma excitation region such as the first plasma region 415, and a cylindrical portion that faces the showerhead 425. The cylindrical portion may be shaped and dimensioned to control the flow of ionic species passing to the showerhead 425. An adjustable electrical bias may also be applied to the ion suppressor 423 as an additional means to control the flow of ionic species through the suppressor.

The ion suppressor 423 may function to reduce or eliminate the amount of ionically charged species traveling from the plasma generation region to the substrate. Uncharged neutral and radical species may still pass through the openings in the ion suppressor to react with the substrate. The complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 425 in combination with ion suppressor 423 may allow a plasma present in first plasma region 415 to avoid directly exciting gases in substrate processing region 433, while still allowing excited species to travel from chamber plasma region such as the first plasma region 415 into substrate processing region 433. Thus, the chamber may be configured to prevent the plasma from contacting a substrate 455 being etched, which can advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, the oxide material may be further protected by maintaining the plasma remotely from the substrate.

The processing system may further include a power supply 440 electrically coupled with the processing chamber to provide electric power to the faceplate 417, ion suppressor 423, showerhead 425, and/or pedestal 465 to generate a plasma in the first plasma region 415 or substrate processing region 433. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the first plasma region 415. Providing a tunable plasma, in turn, may advantageously allow development of particular plasma characteristics such that precursors may be dissociated in specific ways to enhance the etching profiles produced by these precursors.

A plasma may be ignited either in chamber plasma region such as the first plasma region 415 above showerhead 425 or substrate processing region 433 below showerhead 425. Plasma may be present in chamber plasma region such as the first plasma region 415 to produce the radical precursors from an inflow of, for example, a chlorine-containing precursor or other precursor. An AC voltage typically in the radio frequency (RF) range may be applied between the pedestal 465, and showerhead 425 and/or ion suppressor 423 to ignite a plasma in chamber plasma region such as the first plasma region 415 during deposition. An RF power supply may generate a high RF frequency of 13.56 MHz but may also generate other frequencies alone or in combination with the 13.56 MHz frequency. In embodiments, RF is applied to the pedestal 465.

In some embodiments, after the etching process at 102, the exposed surface 216 (FIG. 2D) may optionally be exposed to a hydrogen-containing plasma to remove etch residue left behind by removal of an oxidized layer. The exposed surface 216 after the etching process is exposed to the hydrogen-containing plasma for a period of between about 10 second and about 300 seconds and the flow rate of the hydrogen gas is between about 500 sccm/s and about 4,000 sccm/s.

Referring back to FIG. 1 at 104, and FIG. 2E the feature 202 is filled by selectively depositing a second metal 226 atop the exposed surface 216 of the first metal 208 within the feature 202 to a second predetermined thickness in a second process chamber (such as process chamber 500 shown in FIG. 5) wherein selectively depositing a second metal 226 is performed without oxygen contacting the exposed surface 216. In embodiments, feature 202 is filled with a metal different than first metal 208 (e.g., cobalt is the first metal 208 and second metal 226 is tungsten). In some embodiments, the deposition at 104 is selective upon the exposed surface 216 to not overburden feature 202 and avoid deposit atop the field 225 of the substrate 200, as shown in FIG. 2E. In some embodiments, the deposition at 104 terminates upon filling the feature, and the substrate 200 may be transferred to a different chamber for positioning the feature 202 adjacent a second feature such as a via as shown in FIG. 2F. In some embodiments, the process chamber suitable for deposition is a CVD chamber. In some embodiments, the process chamber suitable for deposition is a CVD process chamber configured to deposit tungsten. In some embodiments, the process chamber suitable for deposition is a PVD chamber. In some embodiments, the process chamber suitable for deposition is a PVD process chamber configured to deposit tungsten. In some embodiments, from the deposition of the barrier layer to the filling of the feature, the substrate is always in a vacuum environment devoid of oxygen. In embodiments, the first metal and second metal have a thickness between about 3 nm and about 40 nm.

Referring now to FIG. 2F, a second substrate such as substrate 200′ is disposed upon substrate 200. In some embodiments, the second substrate (e.g., substrate 200′) is disposed directly upon substrate 200 (e.g., without any intervening liner or adhesive layers). In embodiments, substrate 200 includes a feature 202 filled as described above. For example, the feature 202 may include a first portion 270 of a first metal such as cobalt, and a second portion 280 comprising a second metal such as tungsten. Substrate 200′ includes a feature 202″ filled with the second metal 281 as described above. For example, the feature 202″ may be a second metal 281 such as tungsten. In embodiments, feature 202 is a trench or via, and feature 202″ is a via. In embodiments, methods of the present disclosure can be used to fabricate low resistance stacked vias (such as feature 202 and 202″) by reducing the contact resistance of vias by eliminating a liner between a lower via 207 and an upper via such as feature 202″. In embodiments, after the deposition of the second metal 281 e.g., selective tungsten or second portion 280, a second dielectric layer 212′ is deposited and the upper vias (such as feature 202″) are patterned. The upper vias (such as feature 202″) are then filled with the same metal material that was used as the second metal in substrate 200 (such as tungsten or ruthenium). In embodiments, the methods are suitable to reduce the contact resistance of features such as vias by eliminating a liner between the lower and the upper vias in a stack 295 ensuring low via contact resistance.

Referring back to FIG. 2E, in some embodiments, the first metal 208 is deposited in a PVD chamber and the second metal 226 is deposited in a CVD chamber. Alternatively, in some embodiments, the first metal 208 is deposited in a CVD chamber and the second metal 226 is deposited in a CVD chamber.

In embodiments, a suitable deposition chamber for depositing a second metal such as tungsten is a CVD process chamber 500. Such a process chamber 500 is available from Applied Materials, Inc. located in Santa Clara, Calif. In embodiments, the process chamber 500 may be part of a processing system shown in FIG. 6 including multiple processing chambers connected to a central transfer chamber and serviced by a robot. The process chamber 500 includes walls 506, a bottom 508, and a lid 510 that define a process volume 512. The walls 506 and bottom 508 are typically fabricated from a unitary block of aluminum. The walls 506 may have conduits (not shown) therein through which a fluid may be passed to control the temperature of the walls 506. The process chamber 500 may also include a pumping ring 514 that couples the process volume 512 to an exhaust port 516 as well as other pumping components (not shown). A substrate support assembly 538, which may be heated, may be centrally disposed within the process chamber 500. The substrate support assembly 538 supports a substrate 503 during a deposition process. The substrate support assembly 538 generally is fabricated from aluminum, ceramic or a combination of aluminum and ceramic and typically includes a vacuum port (not shown) and at least one or more heating elements 532.

In embodiments, a vacuum port may be used to apply a vacuum between the substrate 503 and the substrate support assembly 538 to secure the substrate 503 to the substrate support assembly 538 during the deposition process. The one or more heating elements 532, may be, for example, electrodes disposed in the substrate support assembly 538, and coupled to a power source 530, to heat the substrate support assembly 538 and substrate 503 positioned thereon to a predetermined temperature.

In embodiments, the substrate support assembly 538 is coupled to a stem 542. The stem 542 provides a conduit for electrical leads, vacuum and gas supply lines between the substrate support assembly 538 and other components of the process chamber 500. Additionally, the stem 542 couples the substrate support assembly 538 to a lift system 544 that moves the substrate support assembly 538 between an elevated position (as shown in FIG. 5) and a lowered position (not shown). Bellows 546 provide a vacuum seal between the process volume 512 and the atmosphere outside the process chamber 500 while facilitating the movement of the substrate support assembly 538.

The substrate support assembly 538 additionally supports a circumscribing shadow ring 548. The shadow ring 548 is annular in form and typically comprises a ceramic material such as, for example, aluminum nitride. Generally, the shadow ring 548 prevents deposition at the edge of the substrate 503 and substrate support assembly 538.

The lid 510 is supported by the walls 506 and may be removable to allow for servicing of the process chamber 500. The lid 510 may generally be comprised of aluminum and may additionally have heat transfer fluid channels 524 formed therein. The heat transfer fluid channels 524 are coupled to a fluid source (not shown) that flows a heat transfer fluid through the lid 510. Fluid flowing through the heat transfer fluid channels 524 regulates the temperature of the lid 510.

A mixing block 534 may be disposed in the lid 510. The mixing block 534 may be coupled to gas sources 504. Generally, individual gas streams from the gas sources 504 may be combined in the mixing block 534. These gases are mixed into a single homogeneous gas flow in the mixing block 534 and introduced into the process volume 512 after passing through a showerhead 518 that diffuses the gas flow outwardly towards the walls 506.

The showerhead 518 may generally be coupled to an interior side 520 of the lid 510. A perforated blocker plate 536 may optionally be disposed in the space 522 between the showerhead 518 and lid 510. Gases (i.e., process and other gases) that enter the process chamber 500 through the mixing block 534 are first diffused by the blocker plate 536 as the gases fill the space 522 behind the showerhead 518. The gases then pass through the showerhead 518 and into the process chamber 500. The blocker plate 536 and the showerhead 518 are configured to provide a uniform flow of gases to the process chamber 500.

In some embodiments, at least one of the lines supplying process gas, such as the tungsten-containing compound gas, from gas sources 504 to process chamber 500 advantageously includes a valve (not shown) for diverting gas flow, so that during purging of the process chamber 500 the mass flow controller (MFC) for the tungsten-containing compound gas source does not need to be shut off. Diverting the flow of the tungsten-containing compound during purge steps, as opposed to shutting off the flow, reduces overall throughput time by eliminating the extra time needed for the MFC to stabilize the flow of tungsten-containing compound after each purge step.

The process chamber 500 can be controlled by a microprocessor controller 554. The microprocessor controller may be one of any form of general purpose computer processor or central processing unit (CPU) that can be used in an industrial setting for controlling various chambers and sub-processors. The computer processor may use any suitable memory, such as random access memory, read only memory, floppy disc drive, hard disk, or any other form of digital storage, local or remote. Various support circuits may be coupled to the CPU for supporting the processor in a conventional manner. Software routines, as required, may be stored in the memory or executed by a second CPU that is remotely located.

The software routines are executed after the substrate is positioned on the substrate support. The software routines, when executed, transform the general purpose computer into a specific process computer that controls the chamber operation so that a chamber process is performed. Alternatively, the software routines may be performed in hardware as an application specific integrated circuit or other type of hardware implementation, or a combination of software and hardware. In some embodiments, the present disclosure relates to a computer readable medium, having instructions stored thereon which, when executed, cause two or more processing chambers to perform a method of filling a feature disposed in a substrate, including: (a) etching a first metal within the feature to remove a first portion of the first metal at a top of the feature in a first process chamber (such as process chamber 400) to form an exposed surface of the first metal; and (b) selectively depositing a second metal atop the exposed surface of the first metal within the feature to a second predetermined thickness in a second process chamber (such as process chamber 500); wherein etching the first metal and selectively depositing a second metal are performed without oxygen contacting the exposed surface. In embodiments, the first metal is cobalt and the second metal is tungsten.

Non-limiting examples of reaction reagents and conditions for selectively forming a tungsten layer are described in commonly owned U.S. Pat. No. 8,071,478 entitled Method of depositing tungsten film with reduced resistivity and improved surface morphology to Wu et al. In embodiments, depositing a tungsten metal includes depositing a bulk tungsten layer on a substrate during a first deposition stage by (i) introducing a continuous flow of a reducing gas and a pulsed flow of a tungsten-containing compound to a process chamber to deposit tungsten on a surface of the substrate, (ii) flowing the reducing gas without flowing the tungsten-containing compound into the chamber to purge the chamber, and repeating steps (i) through (ii) until the first film fills vias in the substrate surface, increasing the pressure in the process chamber, and during a second deposition stage after the first deposition stage, depositing a second film of the bulk tungsten layer by providing a flow of reducing gas and tungsten-containing compound to the process chamber until a second desired thickness is deposited. In some embodiments, following formation using a CVD process of a nucleation layer of desired thickness of about 30 angstroms using WF₆ and B₂H₆ as reagents on a substrate having vias with a top critical dimension of about 50 nm and about a 4:1 aspect ratio, the substrate may be maintained in the CVD chamber and a bulk tungsten layer may be deposited using a two-stage deposition or fill method.

The methods described herein may be performed in individual process chambers that may be provided in a standalone configuration or as part of one or more cluster tools, for example, an integrated tool 600 (i.e., cluster tool) described below with respect to FIG. 6. Examples of the integrated tool 600 include the ENDURA®, CENTURA®, or PRODUCER® line of processing systems, available from Applied Materials, Inc., of Santa Clara, Calif. However, the methods described herein may be practiced using other cluster tools having suitable process chambers coupled thereto, or in other suitable process chambers. For example, in some embodiments the inventive methods discussed above may advantageously be performed in an integrated tool such that there are limited or no vacuum breaks between processing steps.

The integrated tool 600 can include two load lock chambers 606A, 606B for transferring of substrates into and out of the integrated tool 600. Typically, since the integrated tool 600 is under vacuum, the load lock chambers 606A, 606B may pump down the pressure within the load lock chambers when substrates are introduced into the integrated tool 600. A first robot 610 may transfer the substrates between the load lock chambers 606A, 606B, and a first set of one or more substrate processing chambers 612, 614, 616, 618 (four are shown) coupled to a first transfer chamber 650. Each substrate processing chamber 612, 614, 616, 618, can be outfitted to perform a number of substrate processing operations. In some embodiments, the first set of one or more substrate processing chambers 612, 614, 616, 618 may include any combination of PVD, ALD, CVD, etch, degas, or pre-clean chambers. For example, in some embodiments, the processing chambers, 612, 614, 616, 618 include two pre-clean chambers and two degas chambers.

The first robot 610 can also transfer substrates to/from two intermediate transfer chambers 622, 624. The intermediate transfer chambers 622, 624 can be used to maintain ultrahigh vacuum conditions while allowing substrates to be transferred within the integrated tool 600. A second robot 630 can transfer the substrates between the intermediate transfer chambers 622, 624 and a second set of one or more substrate processing chambers 632, 634, 635, 636, 638 coupled to a second transfer chamber 655. The substrate processing chambers 632, 634, 635, 636, 638 can be outfitted to perform a variety of substrate processing operations including the methods described above in addition to, physical vapor deposition processes (PVD), chemical vapor deposition (CVD), etching, orientation and other substrate processes. In some embodiments, the second set of one or more substrate processing chambers 632, 634, 635, 636, 638 may include any combination of etch chambers (ALE) configured to etch cobalt, deposition chambers configured to deposit tungsten. For example, in some embodiments, the substrate processing chambers 632, 634, 635, 636, 638 include at least two etch chambers (ALE) configured to etch cobalt, at least two CVD chamber configured to deposit metal such as tungsten, and at least one etch chamber configured to etch the metal such as tungsten. Any of the substrate processing chambers 612, 614, 616, 618, 632, 634, 635, 636, 638 may be removed from the integrated tool 600 if not necessary for a particular process to be performed by the integrated tool 600.

In embodiments, FIG. 6 refers to a cluster tool 600, including: a first transfer chamber 650 and a second transfer chamber 655; a substrate processing chamber 632 such as an atomic layer etching (ALE) chamber configured to etch a first metal coupled to the second transfer chamber 655 (however an atomic layer etching (ALE) chamber configured to etch a first metal may be coupled to the first transfer chamber 650); and a substrate processing chamber 634 (such as chemical vapor deposition (CVD) chamber configured to deposit a second metal coupled to the first transfer chamber or second transfer chamber); wherein the integrated tool 600 is configured to transfer from the substrate processing chamber 632 (such as atomic layer etching (ALE) chamber) to the substrate processing chamber 634 (such as chemical vapor deposition (CVD) chamber) under continuous vacuum. In embodiments, the cluster tool or integrated tool 600 is configured to transfer from the substrate processing chamber 632 (such as atomic layer etching (ALE) chamber) to the substrate processing chamber 634 configured as a chemical vapor deposition (CVD) chamber, without oxygen.

In embodiments, the cluster tool or integrated tool 600 further comprising at least one pre-clean chamber such as substrate processing chamber 612 coupled to the first transfer chamber 650 or a second transfer chamber 651. In embodiments, the cluster tool or integrated tool 600 further comprises an atomic layer etching (ALE) chamber configured to etch the second metal coupled to the first transfer chamber. In embodiments, the cluster tool or integrated tool 600 further comprises a second atomic layer etching (ALE) chamber configured to etch a first metal coupled to the first transfer chamber. In embodiments, the cluster tool or integrated tool 600 further comprises a second chemical vapor deposition (CVD) chamber configured to deposit the second metal coupled to the first transfer chamber. In embodiments, the cluster tool or integrated tool 600 includes a second atomic layer etching (ALE) chamber configured to etch the second metal coupled to the first transfer chamber 650.

In some embodiments, a cluster tool, includes: a first transfer chamber; an atomic layer etching (ALE) chamber coupled to the first transfer chamber, wherein the atomic layer etching (ALE) chamber is configured to etch a first metal within a feature to remove a first portion of the first metal at a top of the feature in the atomic layer etching (ALE) chamber to form an exposed surface of the first metal; and a chemical vapor deposition (CVD) chamber configured to selectively deposit a second metal atop the exposed surface of the first metal within the feature to a second predetermined thickness in the chemical vapor deposition (CVD) chamber, wherein the cluster tool is configured to transfer from the atomic layer etching (ALE) chamber to the chemical vapor deposition (CVD) chamber under continuous vacuum. In embodiments, the first metal is cobalt and the second metal is tungsten. In some embodiments, the cluster tool is configured to transfer from the atomic layer etching (ALE) chamber to the chemical vapor deposition (CVD) chamber without oxygen. In some embodiments, at least one pre-clean chamber coupled to the first transfer chamber. In embodiments, a cluster tool, includes: a first transfer chamber; and one or more, such as two, atomic layer etching (ALE) chambers coupled to the first transfer chamber, wherein the one or more atomic layer etching (ALE) chambers are configured to etch a first metal within one or more features to remove a first portion of the first metal at a top of the one or more feature in the one or more atomic layer etching (ALE) chambers to form an exposed surface of the first metal; and one or more, such as two chemical vapor deposition (CVD) chambers configured to selectively deposit a second metal atop the exposed surface of the first metal within the one or more features to a second predetermined thickness in the one or more chemical vapor deposition (CVD) chambers, wherein the cluster tool is configured to transfer from the one or more atomic layer etching (ALE) chambers to the one or more chemical vapor deposition (CVD) chamber under continuous vacuum.

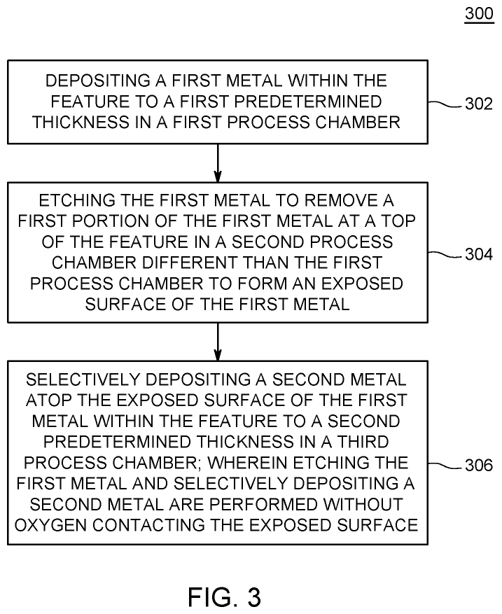

Referring now to FIG. 3, another method of filling a feature disposed in a substrate in accordance with the present disclosure is disclosed. In embodiments, method 300 of filling a feature disposed in a substrate includes at 302 depositing a first metal within the feature to a first predetermined thickness in a first process chamber. In embodiments, leveling the first metal by chemical mechanical planarization may occur after depositing a first metal and prior to etching the first metal. In embodiments, at process sequence 304, methods include etching the first metal to remove a first portion of the first metal at a top of the feature in a second process chamber different than the first process chamber to form an exposed surface of the first metal; and at 306 includes selectively depositing a second metal atop the exposed surface of the first metal within the feature to a second predetermined thickness in a third process chamber; wherein etching the first metal and selectively depositing a second metal are performed without oxygen contacting the exposed surface. In some embodiments, the first predetermined thickness overfills the feature to form an overfilled portion, and wherein the method further comprises removing the overfilled portion using chemical-mechanical planarization. In embodiments, the first predetermined thickness and second predetermined thickness are each between about 3 nm and about 40 nm. In some embodiments, process sequences 302 and 306 are performed using chemical vapor deposition and process sequence 304 is performed using atomic layer etch (ALE). In embodiments, the first metal is cobalt, and the second metal is tungsten or ruthenium. In embodiments, process sequence 306 is performed subsequent to process sequence 304 within a cluster tool under continuous vacuum. In some embodiments, the second process chamber is an etch chamber, and wherein etching comprises: (1) oxidizing an exposed layer of the first metal deposited on the substrate using an oxidizing precursor to form an oxidized layer; (2) purging the oxidizer precursor from the etch chamber; (3) flowing a reducing agent into the etch chamber to react with the oxidized layer and form an organometallic product and etch away the oxidized layer; and (4) purging the organometallic product from the etch chamber. In embodiments, the oxidizing precursor includes a chlorine-containing agent. In some embodiments, oxidizing the exposed layer of the metal includes using a plasma formed from the oxidizing precursor. In some embodiments, the substrate is heated to a temperature between about 100° C. and about 250° C. during etching.

In some embodiments, the present disclosure relates to a computer readable medium, having instructions stored thereon which, when executed, cause two or more process chambers or an integrated tool including at least two or more process chambers to perform a method of filling a feature disposed in a substrate, including: (a) depositing a first metal within the feature to a first predetermined thickness in a first process chamber; (b) etching the first metal to remove a first portion of the first metal at a top of the feature in a second process chamber different than the first process chamber to form an exposed surface of the first metal; and (c) selectively depositing a second metal atop the exposed surface of the first metal within the feature to a second predetermined thickness in a third process chamber; wherein etching the first metal and selectively depositing a second metal are performed without oxygen contacting the exposed surface.

The disclosure may be practiced using other semiconductor substrate processing systems wherein the processing parameters may be adjusted to achieve acceptable characteristics by those skilled in the art by utilizing the teachings disclosed herein. While the foregoing is directed to embodiments of the present disclosure, other and further embodiments of the disclosure may be devised without departing from the basic scope thereof.

1. A method of filling a feature disposed in a substrate, comprising:
(a) etching a first metal within the feature to remove a first portion of the first metal at a top of the feature in a first process chamber to form an exposed surface of the first metal: and
(b) selectively depositing a second metal atop the exposed surface of the first metal within the feature to a second predetermined thickness in a second process chamber; wherein etching the first metal and selectively depositing a second metal are performed without oxygen contacting the exposed surface.

2. The method of claim 1, wherein the first metal is cobalt and the second metal is tungsten.

3. The method of claim 1, wherein the method further comprises removing first metal above the feature using chemical-mechanical planarization.

4. The method of claim 1, wherein the first metal and second metal have a thickness between about 3 nm and about 40 nm.

5. The method of claim 1, wherein (a) is performed using atomic layer etch (ALE).

6. The method of claim 5, wherein the first process chamber is an etch chamber, and etching the first metal comprises:
(1) oxidizing a top surface of the first metal within a feature using an oxidizing precursor to form an oxidized layer;
(2) purging the oxidizer precursor from the etch chamber;
(3) flowing a reducing agent into the etch chamber to react with the oxidized layer and form an organometallic product and etch away the oxidized layer; and
(4) purging the organometallic product from the etch chamber.

7. The method of claim 1, wherein (b) is performed subsequent to (a) within a cluster tool under continuous vacuum.

8. A method of filling a feature disposed in a substrate, comprising:
(a) depositing a first metal within the feature to a first predetermined thickness in a first process chamber;
(b) etching the first metal to remove a first portion of the first metal ata top of the feature in a second process chamber different than the first process chamber to form an exposed surface of the first metal; and
(c) selectively depositing a second metal atop the exposed surface of the first metal within the feature to a second predetermined thickness in a third process chamber; wherein etching the first metal and selectively depositing a second metal are performed without oxygen contacting the exposed surface.

9. The method of claim 8, wherein the first predetermined thickness overfills the feature to form an overfilled portion, and wherein the method further comprises removing the overfilled portion using chemical-mechanical planarization.

10. The method of claim 8, wherein the first predetermined thickness and second predetermined thickness are each between about 3 nm and about 40 nm.

11. The method of claim 8, wherein (a) and (c) are performed using chemical vapor deposition and (b) is performed using atomic layer etch (ALE).

12. The method of claim 8, wherein the first metal is cobalt, and the second metal is tungsten or ruthenium.

13. The method of claim 8, wherein (c) is performed subsequent to (b) within a cluster tool under continuous vacuum.

14. The method of claim 8, wherein the second process chamber is an etch chamber; and wherein (b) comprises:
(1) oxidizing an exposed layer of the first metal deposited on the substrate using an oxidizing precursor to form an oxidized layer;
(2) purging the oxidizer precursor from the etch chamber;
(3) flowing a reducing agent into the etch chamber to react with the oxidized layer and form an organometallic product and etch away the oxidized layer; and
(4) purging the organometallic product from the etch chamber.

15. The method of claim 14, wherein the oxidizing precursor includes a chlorine-containing agent.

16. The method of claim 14, wherein oxidizing the exposed layer includes using a plasma formed from the oxidizing precursor.

17. The method of claim 14, wherein the substrate is heated to a temperature between about 100° C. and about 250° C. during etching.

18. A cluster tool, comprising:
a first transfer chamber;
an atomic layer etching (ALE) chamber coupled to the first transfer chamber, wherein the atomic layer etching (ALE) chamber is configured to etch a first metal within a feature to remove a first portion of the first metal at a top of the feature in the atomic layer etching (ALE) chamber to form an exposed surface of the first metal; and
a chemical vapor deposition (CVD) chamber configured to selectively deposit a second metal atop the exposed surface of the first metal within the feature to a second predetermined thickness in the chemical vapor deposition (CVD) chamber, wherein the cluster tool is configured to transfer from the atomic layer etching (ALE) chamber to the chemical vapor deposition (CVD) chamber under continuous vacuum, and wherein the first metal is cobalt and the second metal is tungsten.

19. The cluster tool of claim 18, wherein the cluster tool is configured to transfer from the atomic layer etching (ALE) chamber to the chemical vapor deposition (CVD) chamber without oxygen.

20. The cluster tool of claim 18, further comprising at least one pre-clean chamber coupled to the first transfer chamber.
